(19) United States
(12) Patent Application Publication
(10) Pub. No.: US 2009/0108362 A1
(43) Pub. Date: Apr. 30, 2009

(54) SEMICONDUCTOR DEVICE AND METHOD OF MANUFACTURING THE SAME

(75) Inventor: Yoshikazu MORIWAKI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/252,566

(22) Filed: Oct. 16, 2008

(30) Foreign Application Priority Data
Oct. 26, 2007 (JP) 2007-279094

(51) Int. Cl. H01L 21/336; H01L 29/78

(52) U.S. Cl. 257/368; 438/294; 257/E29.255; 257/E21.409

(57) ABSTRACT

A semiconductor device includes a semiconductor substrate, an isolation region including an insulator in a trench formed in the semiconductor substrate, an active region including a semiconductor region surrounded by the insulator in the trench and a single-crystal silicon layer formed on the semiconductor region, a gate insulating film formed on the single-crystal silicon layer, a gate electrode provided on the gate insulating film so as to stride across the active region, and diffusion layers provided in the active region on opposite sides of the gate electrode.

### BACKGROUND OF THE INVENTION

1. Field of the Invention

The present invention relates to a semiconductor device and a method of manufacturing the semiconductor device, and in particular, to a semiconductor device including an isolation region having an STI (Shallow Trench Isolation) structure, and a method of manufacturing the semiconductor device.

2. Description of Related Art

MOS transistors mounted in a semiconductor integrated circuit are electrically separated from each other by an isolation region. The separated MOS transistors can be independently controlled.

A LOCOS (Local Oxidation of Silicon) structure formed utilizing a selective oxidation method has been used for the isolation region. However, since the LOCOS structure disadvantageously has difficulty allowing elements to be miniaturized, an STI (Shallow Trench Isolation) structure is now used as a main isolation structure.

A method of forming the STI structure will be described below with reference to FIGS. 1A and 2A to 2I.

FIG. 1A shows a plan view of a MOS transistor. FIGS. 2A to 2I show sectional views of the MOS transistor taken along line Y-Y′ in FIG. 1A, illustrating a series of steps.

With reference to FIG. 1A, an elliptic active region 1a is located on a silicon substrate (hereinafter referred to as a “Si substrate”) with a longitudinal direction of the active region 1a set obliquely. The active region 1a is enclosed by an isolation region 13. Two gate electrodes 10 corresponding to two transistors are arranged on the active region 1a so as to stride across the active region. A source/drain diffusion layer is formed in a part of the active region in which the gate electrodes are not arranged. A part of the active region which is sandwiched between the two gate electrodes 10 is used for the diffusion layer common to the two transistors. A recess portion 8 is formed around the periphery of the active region 1a.

Now, an example of a conventional method of manufacturing a MOS transistor will be described with reference to FIGS. 2A to 2I.

First, as shown in FIG. 2A, a pad film 2 made up of a silicon oxide film is formed on a Si substrate 1 by normal thermal oxidation, A mask film 3 made up of a silicon nitride film is then formed.

Then, as shown in FIG. 2B, a part of the silicon nitride film which includes a region corresponding to an isolation region to be formed later is removed by a normal lithography method and a normal anisotropic dry etching method. A silicon oxide film 4 is subsequently formed all over the resulting surface.

Then, as shown in FIG. 2C, the silicon oxide film 4 is etched back by the normal anisotropic dry etching method to form a sidewall 5. The mask film 3 and the sidewall 5 are used as a mask to etch the exposed Si substrate 1 to form a trench 6.

Then, the sidewall 5 is removed by wet etching using an HF-containing chemical. Thereafter, as shown in FIG. 2D, a silicon oxide film 7 is deposited by a normal plasma CVD (Chemical Vapor Deposition) method to bury the trench 6.

Then, as shown in FIG. 2E, the silicon oxide film 7 is polished and removed by a CMP (Chemical Mechanical Polishing) method. The silicon oxide film 7 is subsequently etched by the wet etching method using a HF-containing chemical so that the height of the silicon oxide film 7 is adjusted to a predetermined value.

Then, as shown in FIG. 2F, the mask film 3 and the pad film 2 are removed by the wet etching method. As a result, the silicon oxide film 7 in the trench 6 forms an isolation region 13. At this time, as shown in FIGS. 2F and 1A, a recess portion 8 is formed in a boundary portion between the isolation region 13 and the active region 1a.

Subsequently, a channel dopant is implanted into the active region 1a by an ion implantation method. The dopant is implanted deeper below the recess portion 8 than in the normal active region excluding the recess portion.

Then, as shown in FIG. 2G, a gate insulating film 15 is formed by the normal thermal oxidation method. A polycrystalline silicon film 9 serving as a gate electrode is subsequently deposited by a low-pressure CVD method.

Then, as shown in FIG. 2H, the polycrystalline silicon film 9 is patterned by the normal lithography method and the normal anisotropic dry etching method to form a gate electrode 10. At this time, an etching residue 11 of the polycrystalline silicon film 9 is generated in the recess portion 8.

Then, as shown in FIG. 2I, a source diffusion layer 16 and a drain diffusion layer 17 are formed by the ion implantation method. As a result, a transistor made up of the gate insulating film 15, the gate electrode 10, the source diffusion layer 16, and the drain diffusion layer 17 is formed in the active region.

According to the above-described related art, the mask made up of the silicon oxide film (pad film 2) and the silicon nitride film (mask film 3) is formed on the active region. The trench 6 is formed by the dry etching method using the mask. Thereafter, the silicon oxide film 7 is deposited all over the resulting surface. The silicon oxide film 7 in the trench 6 is polished by the CMP method and wet etched so that the height of the silicon oxide film 7 is reduced to an intended value. The mask (pad film 2 and mask film 3) thereafter needs to be removed. However, since the removal is performed by isotropic wet etching, the recess portion 8 is generated in the boundary portion between the isolation region 13 and the active region. A shoulder portion of an active region-end at the boundary portion is rounded in order to inhibit concentration of electric fields on the gate insulating film. This allows the recess portion 8 to be significantly generated.

The generation of the recess portion 8 locally varies a dopant implantation depth in the implantation of the channel dopant, and causes the etching residue 11 to be generated in the recess portion 8 during etching of the gate forming polycrystalline silicon film 9. These phenomena have become more obvious as semiconductor integrated circuits have been more highly integrated.

The varying dopant implantation depth degrades the current-voltage property of the transistor, and reduces the design width of the MOS transistor. These make miniaturizing the MOS transistor difficult.

The generated etching residue short-circuits adjacent gate electrodes as shown in FIG. 1B. FIG. 1B shows a cross section taken along line X-X′ in FIG. 1A. FIG. 1B shows that the generated etching residue of the polycrystalline silicon film forms a short-circuit portion 14 to short-circuit the adjacent gate electrodes 10. When short-circuited, the adjacent transistors cannot operate independently.

A reduction in wiring width resulting from miniaturization has increased a difference in etching rate for dry etching caused by a difference in pattern density. The etching residue has thus become likely to be generated in the recess portion. The difference in etching rate caused by the difference in pattern density means that the etching rate is high in a region with a coarse pattern and is low in a region with a dense pattern. When required conditions are set on the basis of the region with the high etching rate in order to inhibit excessive etching, the etching residue is likely to be generated in the region with the low etching rate.

Japanese Patent Laid-Open No. 2006-222329 describes that a recess portion (divot) is disadvantageously generated at an edge of a silicon surface at the boundary between the isolation region and the active region in the STI structure. This gazette further describes that the gate electrode is formed so as to cover an edge of at least one of the source diffusion layer and the drain diffusion layer in order to solve this problem.

Japanese Patent Laid-Open No. 2002-190514 similarly describes that the recess portion is disadvantageously formed at the boundary between the isolation region and the active region. This gazette further describes that a LOCOS oxide film is formed in the boundary portion in order to solve this problem.

Japanese Patent Laid-Open No. 11-354784 describes that in a field effect transistor having an elevated diffusion layer structure in which a silicon layer is formed on a region in which a source-drain diffusion layer is formed as well as the STI structure, a recess portion is disadvantageously formed in the boundary region between the silicon layer and the isolation region. This gazette further describes that the recess portion is filled with a semiconductor material in order to solve this problem.

### SUMMARY

In one embodiment, there is provided a semiconductor device including:

a semiconductor substrate;

an isolation region including an insulator in a trench formed in the semiconductor substrate;

an active region including a semiconductor region surrounded by the insulator in the trench and a single-crystal silicon layer formed on the semiconductor region;

a gate insulating film formed on the single-crystal silicon layer; a gate electrode provided on the gate insulating film, the gate electrode striding across the active region; and

diffusion layers provided in the active region on opposite sides of the gate electrode.

In another embodiment, there is provided the above-described semiconductor device, further including a recess along a boundary between the insulator in the trench and the semiconductor region, wherein the single-crystal silicon layer fills the recess.

In another embodiment, there is provided any one of the above-described semiconductor devices, wherein an upper layer side portion of the active region, the upper layer side portion including the single-crystal silicon layer, extends in a planar direction of the substrate all along a periphery of the active region with respect to a lower layer side portion of the active region.

In another embodiment, there is provided any one of the above-described semiconductor devices, further including another gate electrode striding across the active region.

In another embodiment, there is provided a semiconductor device including:

a semiconductor substrate;

an isolation region including an insulator in a trench formed in the semiconductor substrate;

an active region surrounded by the isolation region;

a gate insulating film formed on the active region;

a gate electrode provided on the gate insulating film, the gate electrode striding across the active region; and

diffusion layers provided in the active region on opposite sides of the gate electrode,

wherein an upper surface side portion of the active region extends in a planar direction of the substrate all along a periphery of the active region with respect to a lower side portion of the active region.

In another embodiment, there is provided the above-described semiconductor devices, further including another gate electrode striding across the active region.

In another embodiment, there is provided a method of manufacturing a semiconductor device, the method including:

forming a first oxide film on a semiconductor substrate;

forming a mask on the first oxide film;

forming a trench on the semiconductor substrate by etching using the mask to form a semiconductor region surrounded by the trench;

forming a second oxide film all over a resulting surface such that the second oxide film fills the trench;

removing a part of the second oxide film such that the mask is exposed with the trench remaining filled with the second oxide film;

removing the mask;

removing the first oxide film by wet etching such that the semiconductor region surrounded by the second oxide film in the trench is exposed;

forming a single-crystal silicon layer on the exposed surface of the semiconductor region to form an active region including the single-crystal silicon layer and the semiconductor region;

forming a gate insulating film on the single-crystal silicon layer;

forming a gate electrode striding across the active region by forming a conductive layer on the gate insulating film and patterning the conductive layer; and

forming diffusion layers on opposite sides of the gate electrode by doping impurity into the active region.

In another embodiment, there is provided the above-described method of manufacturing the semiconductor device, wherein in the wet etching, a recess is formed along a boundary between the second oxide film in the trench and the semiconductor region, and the single-crystal silicon layer fills the recess.

In another embodiment, there is provided any one of the above-described method of manufacturing the semiconductor device, wherein the single-crystal silicon layer is formed by an epitaxial growth method.

In another embodiment, there is provided any one of the above-described methods of manufacturing the semiconductor device, wherein after the single-crystal silicon layer is formed, channel impurity is doped into the active region.

The present invention can provide a fine semiconductor device with excellent element characteristics.

### BRIEF DESCRIPTION OF THE DRAWINGS

The features and advantages of the present invention will be more apparent from the following description of certain preferred embodiments taken in conjunction with the accompanying drawings; in which:

FIG. 1A is a plan view of a MOS transistor illustrating problems with the related art;

FIG. 1B is a sectional view of the MOS transistor illustrating the problems with the related art;

FIG. 2A is a sectional view illustrating a step of a conventional method of manufacturing a MOS transistor;

FIG. 2B is a sectional view illustrating a step succeeding the step shown in FIG. 2A;

FIG. 2C is a sectional view illustrating a step succeeding the step shown in FIG. 2B;

FIG. 2D is a sectional view illustrating a step succeeding the step shown in FIG. 2C;

FIG. 2E is a sectional view illustrating a step succeeding the step shown in FIG. 2D;

FIG. 2F is a sectional view illustrating a step succeeding the step shown in FIG. 2E;

FIG. 2G is a sectional view illustrating a step succeeding the step shown in FIG. 2F;

FIG. 2H is a sectional view illustrating a step succeeding the step shown in FIG. 2G;

FIG. 2I is a sectional view illustrating a step succeeding the step shown in FIG. 2H;

FIG. 3A is a sectional view illustrating a step of a method of manufacturing a MOS transistor according to an embodiment of the present invention;

FIG. 3B is a sectional view illustrating a step succeeding the step shown in FIG. 3A;

FIG. 3C is a sectional view illustrating a step succeeding the step shown in FIG. 3B;

FIG. 3D is a sectional view illustrating a step succeeding the step shown in FIG. 3C;

FIG. 3E is a sectional view illustrating a step succeeding the step shown in FIG. 3D;

FIG. 3F is a sectional view illustrating a step succeeding the step shown in FIG. 3E;

FIG. 3G is a sectional view illustrating a step succeeding the step shown in FIG. 3F;

FIG. 3H is a sectional view illustrating a step succeeding the step shown in FIG. 3G;

FIG. 3I is a sectional view illustrating a step succeeding the step shown in FIG. 3H;

FIG. 3J is a sectional view illustrating a step succeeding the step shown in FIG. 3I; and

FIG. 3K is a sectional view illustrating a step succeeding the step shown in FIG. 3J.

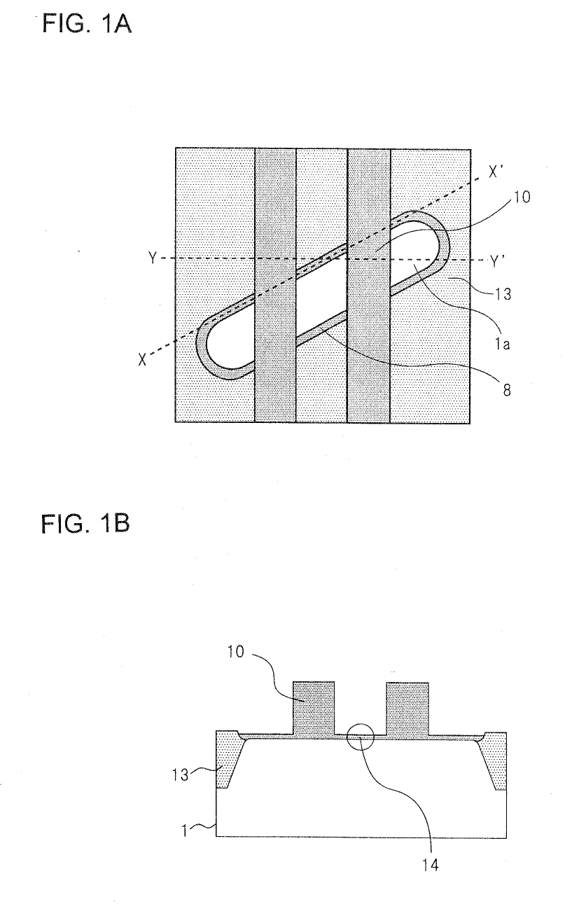

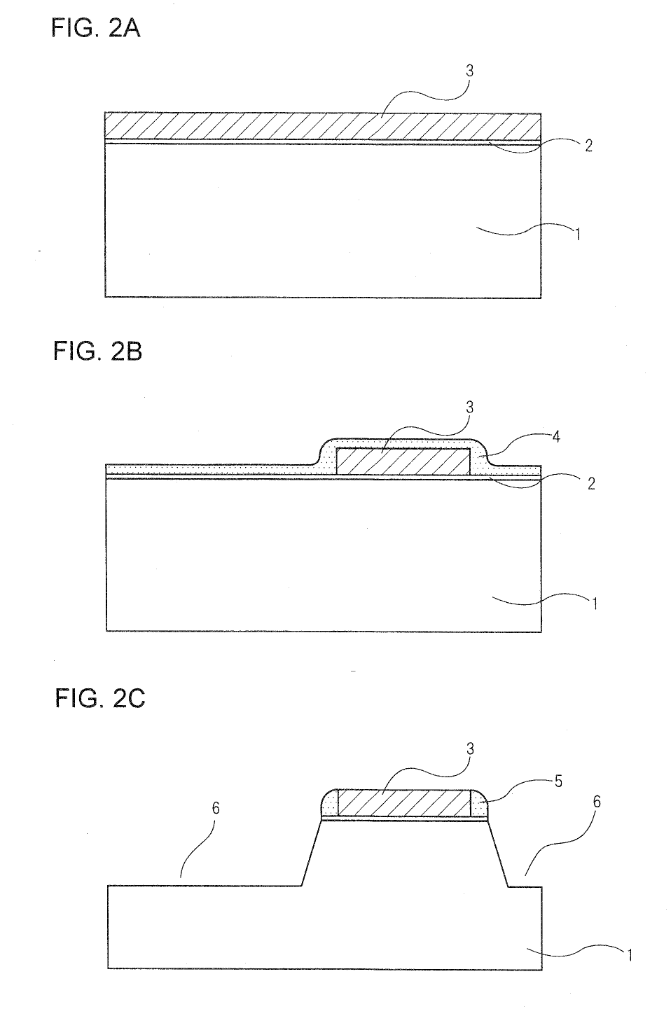

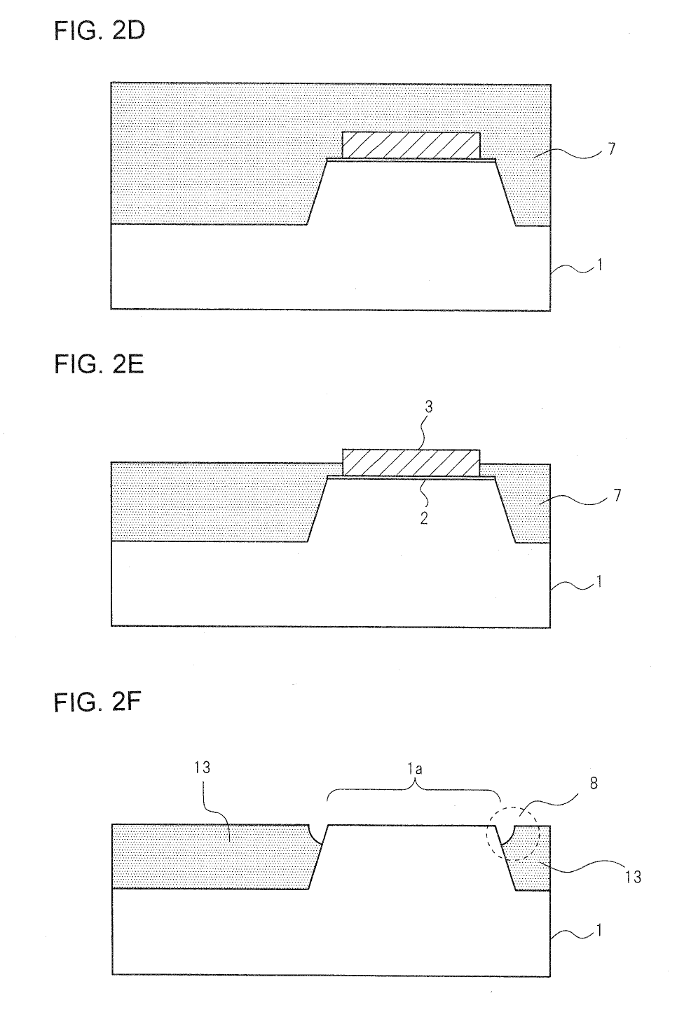

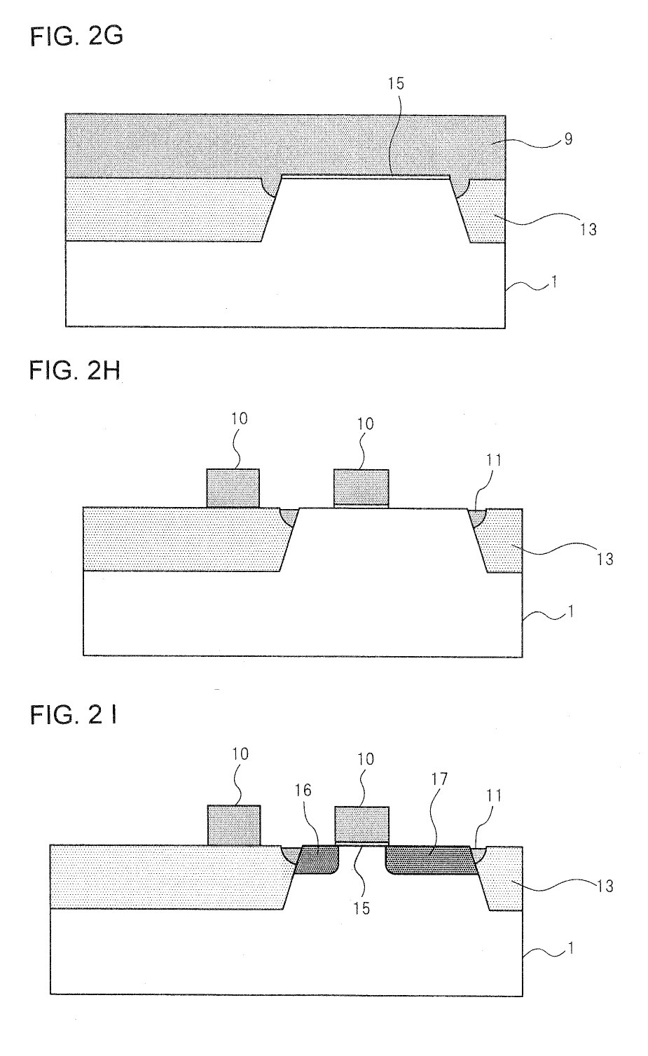

### DETAILED DESCRIPTION OF THE PREFERRED EMBODIMENTS

According to one embodiment of the present invention, a single-crystal silicon (hereinafter referred to as “single-crystal Si”) layer can be provided so as to fill a recess portion generated at a boundary between an active region (semiconductor) and an isolation region (insulator) in an STI structure. This prevents the above-described problems resulting from the recess portion, enabling provision of a fine semiconductor device with excellent element characteristics.

The single-crystal Si layer can be grown, by an epitaxial growth method, on an exposed surface of a semiconductor portion (hereinafter referred to as an “active region portion”) surrounded by an insulator in a trench. That is, the single-crystal Si layer can be provided so as to cover the entire part which is not covered with the insulator in the trench, in the active region portion of the semiconductor substrate.

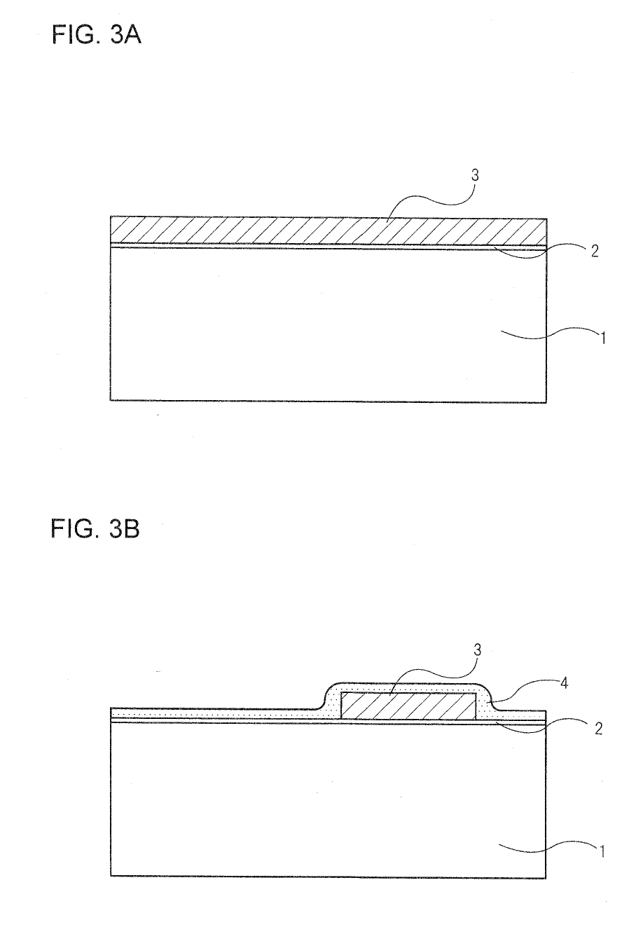

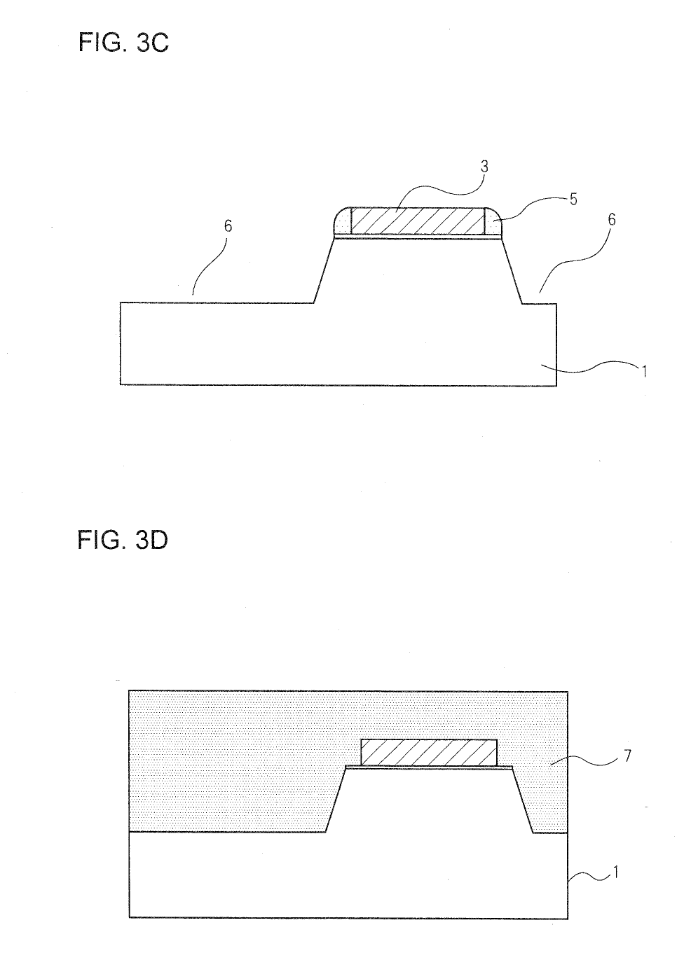

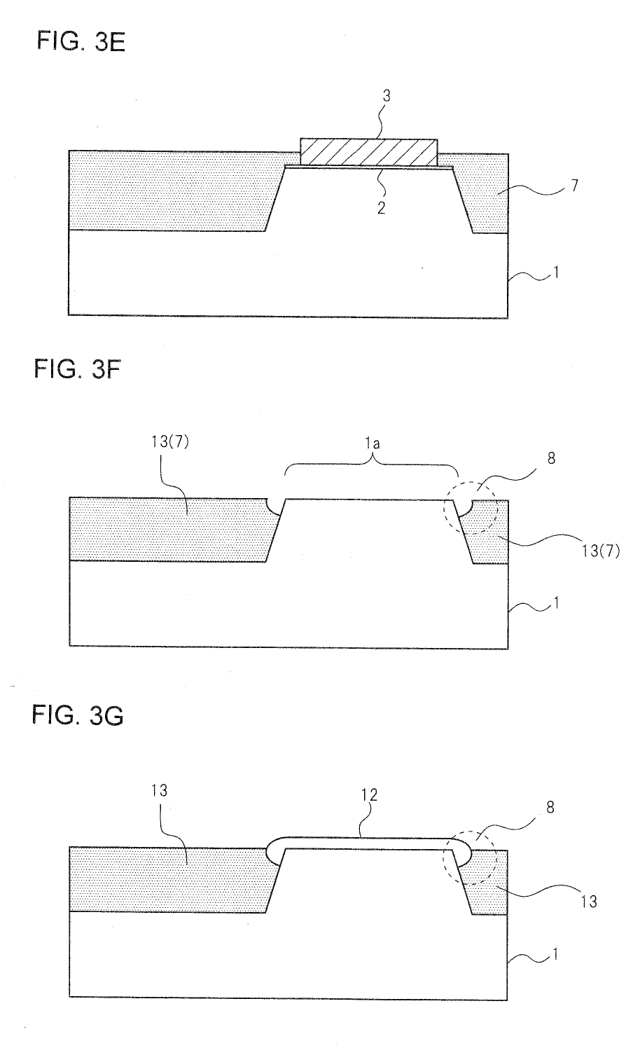

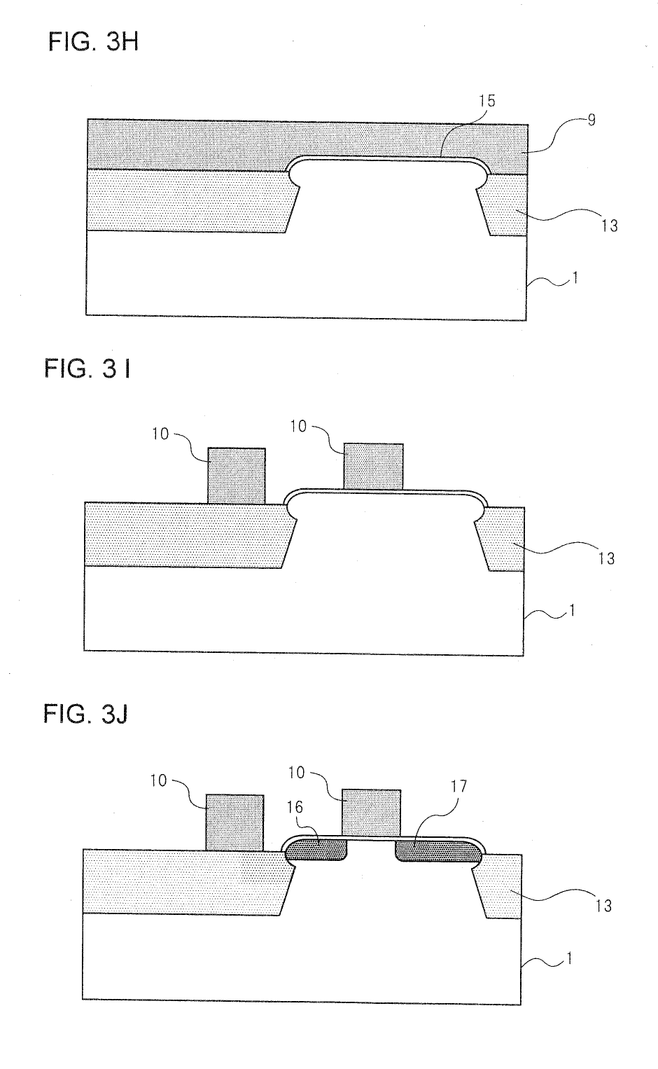

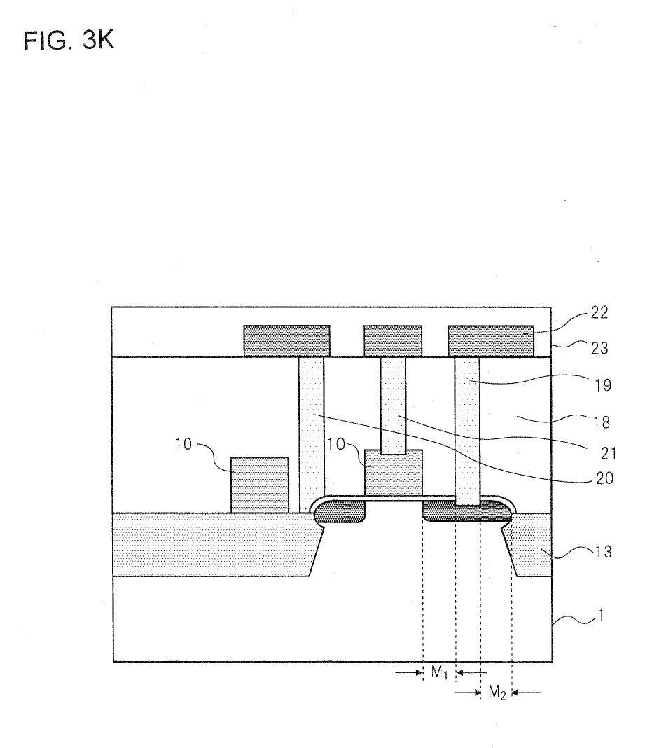

In the active region (the region including the active region portion of the semiconductor substrate and the single-crystal Si layer) according to the embodiment of the present invention, an upper layer side portion extends in a planar direction of the substrate all along the periphery of the active region with respect to a lower layer side portion. Thus, as shown in FIG. 3K, described below, a field-contact margin M2 can be made larger than a gate-contact margin M1. As a result, the contact area of the contact can be increased, enabling a reduction in contact resistance.

An example of a method of manufacturing a MOS transistor according to the present invention will be described with reference to FIGS. 3A to 3K.

First, as shown in FIG. 3A, a pad film 2 made up of a silicon oxide film is formed on a Si substrate (silicon substrate) 1 to a thickness of 5 to 20 nm by a normal thermal oxidation method. Then, a mask film 3 made up of a silicon nitride film is formed to a thickness of 50 to 200 nm by a normal low-pressure-and-low-temperature CVD method.

Then, as shown in FIG. 3B, the mask film 3, made up of the silicon nitride film, is patterned by a normal lithography method and a normal anisotropic dry etching method to remove a part of the silicon nitride film which includes a region corresponding to an isolation region to be formed later. The silicon oxide film 4 is subsequently formed to a thickness of 5 to 20 nm by the normal low-pressure-and-low-temperature CVD method.

Then, as shown in FIG. 3C, the silicon oxide film 4 is etched back by the normal anisotropic dry etching to form a sidewall 5. At this time, the pad film 2, made up of the silicon oxide film, is also etched to expose a surface of the Si substrate 1. The exposed Si substrate 1 is dry etched through the mask film 3 and the sidewall 5 as a mask to form a trench 6 of depth about 250 nm. The operation from the formation of the sidewall 5 through the formation of the trench 6 is desirably consecutively performed in the same etching apparatus. In this case, a protective oxide film may be formed on an inner wall of the trench by a method such as thermal oxidation.

Then, the sidewall 5 is removed by wet etching using a hydrofluoric acid (HF)-containing chemical. Thereafter, as shown in FIG. 3D, an STI film 7 made up of a silicon oxide film is deposited to a thickness of 300 to 600 nm by a normal plasma CVD method so as to completely fill the trench 6.

Then, as shown in FIG. 3E, the STI film 7, made up of the silicon oxide film, is polished and removed by a GMP method. Once a surface of the mask film 3, made up of the silicon nitride film, is exposed, the polishing and removal operation is stopped. The STI film 7 is subsequently etched by the wet etching method using an HF-containing chemical. For the etching, etching conditions are adjusted such that a surface of the STI film 7 is positioned about 30 nm higher than the surface of the Si substrate 1 located outside the trench.

Then, as shown in FIG. 3F, the mask film 3, made up of the silicon nitride film, is etched away using phosphoric acid (H3PO4) heated to about 170° C. The pad film 2, made up of the silicon oxide film, is etched away using the HF-containing chemical. As a result, an isolation region 13 made up of the STI film (silicon oxide film) 7 in the trench 6 is formed. At this time, a recess portion 8 is formed along the boundary between the isolation region 13 and the active region 1a on the STI film side. That is, a part of the Si substrate 1 which forms the active region 1a (the active region portion surrounded by the STI film 7) is exposed at a top surface thereof and a side surface thereof in the recess portion 8.

Then, as shown in FIG. 3G, a natural oxidation film formed on the exposed surface of the active region portion of the Si substrate 1 is removed by wet etching. A single-crystal Si layer 12 is grown on the exposed surface of the active region portion of the Si substrate by selective epitaxial growth. The thickness of the single-crystal Si layer 12 can be set to 5 to 20 nm. The growth of the single-crystal Si layer 12 forms the single-crystal Si layer covering the entire exposed surface of the active region portion of the Si substrate. The interior of the recess portion 8 is filled with the single-crystal Si.

For the selective epitaxial growth, dichlorosilane (SiH₂Cl₂) and hydrogen chloride (HCl) can be used as a material gas. The selective epitaxial growth can be carried out in a hydrogen (H₂) atmosphere. The atmosphere for the selective epitaxial growth may be at the normal pressure or a reduced pressure. The temperature for the selective epitaxial growth can be set within the range of 750 to 830° C., for example, to 780° C.

A channel dopant is subsequently implanted into the active region 1a by an ion implantation method. About 1E12 to 1E13 (atoms/cm²) of B (boron), a P-type dopant, for an N channel MOS transistor or P (phosphorous), an N-type dopant, for a P channel MOS transistor is implanted into the active region 1a. Since the interior of the recess portion 8 is filled with the single-crystal Si, the dopant is implanted, even below the recess portion 8, to a depth similar to that in the region without the recess portion (a variation in implantation depth is reduced). This prevents the characteristics of the MOS transistor from being degraded by the recess portion 8.

Then, as shown in FIG. 3H, a gate insulating film 15 made up of a silicon oxide film is formed to a thickness of 2 to 10 nm by the normal thermal oxidation method. A polycrystalline silicon film 9 is deposited to a thickness of 50 to 100 nm by a low-pressure-and-low-temperature CVD method. In FIG. 3H and the subsequent figures, the single-crystal Si layer 12 is drawn integrally with the Si substrate 1 because the single-crystal Si layer 12 is formed of the single-crystal Si similarly to the Si substrate 1. For an N-type gate electrode, silane (SiH₄) and phosphine (PH₃) can be used as a material gas, with phosphorous contained in the film as impurities. For a P-type gate electrode, disilane (Si₂H₆) and diboran (B₂H₆) can be used as a material gas, with boron contained in the film as impurities. In either case, the flow rate of the material gas can be set so as to set the concentration of impurities in the film to, for example, 1E20 to 1E21 (atoms/cm³). Desirably, in the deposition stage, the polycrystalline silicon film 9 is formed in an amorphous state, and after the completion of the deposition, is subjected to heat treatment and set to a polycrystalline state. The impurities can also be doped into the polycrystalline silicon film 9 using an ion implantation method, after the completion of the deposition.

Then, as shown in FIG. 3I, the polycrystalline silicon film 9 is patterned by a normal lithography method and a normal anisotropic dry etching method to form a gate electrode 10. Since the interior of the recess portion 8 is filled with the single-crystal Si, no etching residue of the polycrystalline silicon film is generated in the recess portion 8.

Then, as shown in FIG. 3J, a source diffusion layer 16 and a drain diffusion layer 17 are formed by an ion implantation method. About 1E12 to 1E13 (atoms/cm²) of As (arsenic) and P (phosphor) ions, an N-type dopant, for an N channel MOS transistor or B (boron), a P-type dopant, for a P channel MOS transistor is implanted into the active region 1a. After the implantation, a thermal treatment is carried out to activate the dopant.

Then, as shown in FIG. 3K, a first interlayer film 18 is formed by a plasma CVD method after the dopant is subjected to the activation annealing; thereafter a drain contact 19, a source contact 20 and a gate contact 21 are formed according to a normal method (the source contact 20 and the gate contact 21 are not present in a cross section shown in FIG. 3K but are drawn in the same cross section for description). Metal wiring 22 is subsequently formed, and a protect film 23 (second interlayer film) is finally formed to complete the MOS transistor in the present example.

It is apparent that the present invention is not limited to the above embodiments, but may be modified and changed without departing from the scope and spirit of the invention.

What is claimed is:

1. A semiconductor device comprising:
a semiconductor substrate;
an isolation region comprising an insulator in a trench formed in the semiconductor substrate;
an active region including a semiconductor region surrounded by the insulator in the trench and a single-crystal silicon layer formed on the semiconductor region;
a gate insulating film formed on the single-crystal silicon layer;
a gate electrode provided on the gate insulating film, the gate electrode striding across the active region; and
diffusion layers provided in the active region on opposite sides of the gate electrode.

2. The semiconductor device according to claim 1, further comprising a recess along a boundary between the insulator in the trench and the semiconductor region, wherein the single-crystal silicon layer fills the recess.

3. The semiconductor device according to claim 1, wherein an upper layer side portion of the active region, the upper layer side portion including the single-crystal silicon layer, extends in a planar direction of the substrate all along a periphery of the active region with respect to a lower layer side portion of the active region.

4. The semiconductor device according to claim 1, further comprising another gate electrode striding across the active region.

5. A semiconductor device comprising:
a semiconductor substrate;
an isolation region comprising an insulator in a trench formed in the semiconductor substrate;
an active region surrounded by the isolation region;
a gate insulating film formed on the active region;
a gate electrode provided on the gate insulating film, the gate electrode striding across the active region; and
diffusion layers provided in the active region on opposite sides of the gate electrode,
wherein an upper surface side portion of the active region extends in a planar direction of the substrate all along a periphery of the active region with respect to a lower side portion of the active region.

6. The semiconductor device according to claim 5, further comprising another gate electrode striding across the active region.

7. A method of manufacturing a semiconductor device, the method comprising:
forming a first oxide film on a semiconductor substrate;
forming a mask on the first oxide film;
forming a trench on the semiconductor substrate by etching using the mask to form a semiconductor region surrounded by the trench;
forming a second oxide film all over a resulting surface such that the second oxide film fills the trench;
removing a part of the second oxide film such that the mask is exposed with the trench remaining filled with the second oxide film;
removing the mask;
removing the first oxide film by wet etching such that the semiconductor region surrounded by the second oxide film in the trench is exposed;
forming a single-crystal silicon layer on the exposed surface of the semiconductor region to form an active region including the single-crystal silicon layer and the semiconductor region:
forming a gate insulating film on the single-crystal silicon layer;
forming a gate electrode striding across the active region by forming a conductive layer on the gate insulating film and patterning the conductive layer; and
forming diffusion layers on opposite sides of the gate electrode by doping impurity into the active region.

8. The method of manufacturing the semiconductor device according to claim 7, wherein in the wet etching, a recess is formed along a boundary between the second oxide film in the trench and the semiconductor region, and the single-crystal silicon layer fills the recess.

9. The method of manufacturing the semiconductor device according to claim 7, wherein the single-crystal silicon layer is formed by an epitaxial growth method.

10. The method of manufacturing the semiconductor device according to claim 7, wherein after the single-crystal silicon layer is formed, channel impurity is doped into the active region.
